(19) United States
(12) Patent Application Publication
(10) Pub. No.: US 2004/0040506 A1
(43) Pub. Date: Mar. 4, 2004

(54) High throughput deposition apparatus

(76) Inventors: Herbert C. Ovshinsky, Oak Park, MI (US); Kevin Hoffman, Sterling Heights, MI (US); Joachim Doehler, Santa Barbara, CA (US); Mark Lycette, Berkley, MI (US); James Key, Waterford, MI (US)

Correspondence Address: ENERGY CONVERSION DEVICES, INC., 2956 WATERVIEW DRIVE, ROCHESTER HILLS, MI, 48309, US

(21) Appl. No.: 10/228,542

(22) Filed: Aug. 27, 2002

(51) Int. Cl. C23C 16/00

(52) U.S. Cl. 118/718

(57) ABSTRACT

A high throughput apparatus for depositing one or more thin film layers on a plurality of continuous web substrates. The apparatus includes a pay-out unit for dispensing a plurality of webs, a deposition unit that receives the plurality of webs and deposits a series of one or more thin film layers thereon, and a take-up unit that receives and stores the plurality of webs upon deposition of the thin film layers. High throughput is achieved through the simultaneous deposition of thin films on a plurality of web substrates. In a preferred embodiment, deposition occurs through plasma enhanced chemical vapor deposition in which a plasma region is formed between a cathode in the deposition unit and the plurality of webs. Deposition precursors are introduced into the plasma region and are transformed to reactive species that form a thin film layer on the plurality of web substrates. In one embodiment, the deposition unit includes a series of deposition chambers, each of which is operated at conditions that lead to the formation of a thin film layer with an intended composition and thickness. By appropriately selecting deposition precursors and conditions for individual deposition chambers within a series, the instant invention permits the formation of multilayer structures in which the layers vary in composition and/or thickness. In a preferred embodiment, multilayer structures including amorphous, polycrystalline and/or microcrystalline silicon are formed in which the layers may be n-type, p-type or intrinsic. In a preferred embodiment, the plurality of webs is co-planar and parallel to a cathode in the deposition chamber. In another preferred embodiment, a cathode is interposed between two sets of co-planar webs and deposition occurs on both sets of webs simultaneously as plasma regions extend from two surfaces of the cathode. Also disclosed is a web supporter having flexible displacement means for web transport. The supporter facilitates transport by compensating for disturbances in web motion while preventing damage to deposited films.

### FIELD OF THE INVENTION

This invention relates generally to apparatus for the deposition of multilayer material structures on a plurality of substrates. More specifically, this invention relates to the high throughput production of multilayer photovoltaic devices comprising silicon on a plurality of continuous webs that are transported simultaneously through one or more plasma enhanced chemical vapor deposition chambers.

### BACKGROUND OF THE INVENTION

Photovoltaic devices are an established area of research and development and continue to attract great attention. One important application of photovoltaic devices is solar energy. Devices capable of efficiently converting sunlight to electrical energy offer the prospect of harnessing an immense and largely untapped natural source of energy to meet the needs of society. Successful widespread implementation of solar energy devices would greatly reduce the world's dependence on fossil fuels and ameliorate the associated negative consequences of global warming. The practical realization of solar energy requires the development of photovoltaic devices with economically competitive efficiencies and production costs.

The desired attributes for an efficient solar energy device are strong absorption of the full range of wavelengths associated with the solar spectrum, efficient formation of electrical charge carrying species from the absorbed solar light, and high electrical conductivity. Absorption of the full solar spectrum leads to the maximum introduction of energy into a solar energy device. Efficient formation of electrical charge carrying species implies a minimization of losses of the introduced solar energy to thermal and other unproductive processes. High electrical conductivity allows the electrical charge carriers to be efficiently collected from the device for the purposes of powering external devices or performing external functions.

Current solar energy devices perform according to each of the desired attributes to varying degrees. It is difficult to find an economical active material for solar energy devices that is simultaneously highly absorbing over the appropriate broad wavelength range, highly conductive and highly efficient at creating electrical charge carriers. Typically, optimization of one desired attribute comes at the expense of another desired attribute and compromises are necessarily made when designing new solar energy devices. Because of these difficulties, practical solar energy devices are typically multilayer structures comprised of several materials with different compositions or doping. The properties of the layers used in the structures are collectively optimized to maximize the sunlight-to-electricity efficiency. Optimization and further improvement of materials continue to be major goals of research and development.

One commonly used multilayer structure for solar energy devices and other photovoltaics is the n-i-p structure. This structure consists of an i-type (intrinsic) semiconductor layer interposed between an n-type semiconductor layer and a p-type semiconductor layer. In a typical simple device, a transparent conducting electrode layer is contacted to the p-type layer and a metal electrode is contacted to the n-type layer. In such a device, incident sunlight passes through the transparent electrode and p-type layer and is absorbed by the i-type layer. Absorption by the i-type layer leads to promotion of electrons from the valence band to the conduction band and to the formation of electron-hole pairs in the i-type layer. The electrons and holes are the charge carriers needed to produce electricity. The adjacent p-type and n-type layers establish a potential in the i-type layer that separates the electrons and holes. The electrons and holes are subsequently conducted to oppositely charged collection electrodes and made available to power external devices or perform external functions.

Most of today's leading solar energy devices are based on crystalline silicon, amorphous silicon, microcrystalline silicon or related materials, including alloys of silicon with germanium. Other materials such as GaAs, CdS and CuInSe₂ are also used, but less frequently. Amorphous silicon is sufficiently versatile that it can be used to form n-type, i-type or p-type layers. The favorability of using amorphous silicon as the i-type layer results from the high absorbance associated with its direct bandgap. The existence of a direct bandgap in amorphous silicon is unusual in that its well-known crystalline analogue has an indirect gap and is weakly absorbing. The high absorbance of amorphous silicon is desirable because it leads to efficient absorption of sunlight in thinner devices. Thinner devices require less material and are correspondingly more cost effective.

Several improvements to the basic n-i-p structure have been developed over the years to improve the efficiency of amorphous silicon based solar energy devices. These improvements include the use of microcrystalline silicon to form the p-type layer, integration of two or more ni-p structures to form tandem devices, and inclusion of a back reflector in the structure. U.S. Pat. No. 4,609,771, for example, discloses the use of microcrystalline silicon p-type layers in solar cells. The inventors therein demonstrate that microcrystalline silicon has a higher transparency to sunlight than amorphous silicon. As a result, use of a microcrystalline silicon p-type layer allows more incident sunlight to reach the i-type layer and a higher concentration of charge carriers is produced as a result.

The strategy associated with tandem devices is to couple multiple n-i-p structures in series in an attempt to harvest as much incident sunlight as possible. Although high, the absorption efficiency of i-type amorphous silicon layers is substantially less than 100%. Placement of a second n-i-p structure directly below the n-i-p structure that is directly incident to the sunlight provides an opportunity to capture light not absorbed by the first n-i-p structure. Tandem structures that include the stacking of three n-i-p structures to form triple cells have also been described. Additional strategies such as bandgap tailoring of the i-layer from one n-i-p structure to the next have also been demonstrated to improve the light harvesting efficiency of tandem.

Back reflecting layers are reflective layers that are typically deposited directly on the substrate. The role of a back reflecting layer is to reflect any light passing through all of the n-i-p cells stacked in a tandem device. Through this reflection process, light that is initially not absorbed is redirected to the stacked n-i-p devices for a second pass and improved absorption efficiency results.

An important advantage associated with amorphous silicon is the ability to manufacture it in a large scale continuous manufacturing process. Crystalline silicon, on the other hand, can only be prepared in a slow, smaller scale process because of the slow crystallization processes associated with its formation. Consequently, great efforts have been directed at the large scale production of amorphous silicon. Modem web rolling processes permit the high speed production of single and multilayer thin films amorphous silicon based devices. The production of amorphous silicon on a continuous web has been previously described in, for example, U.S. Pat. Nos. 4,485,125; 4,492,181; and 4,423,701, the disclosures of which are hereby incorporated by reference.

Although current web rolling processes provide amorphous silicon-based photovoltaic devices on a large scale, further improvements to production throughput are needed in order for the production of energy from silicon-based photovoltaic devices to compete more effectively with the production of energy from petroleum-based fuels. Continued scale-up of thin film deposition techniques are needed to further lower the per device cost of amorphous silicon based photovolatics. The scale-up must be amenable to the deposition of a wide variety of amorphous silicon based materials (e.g. n-type, p-type, i-type) and other materials (e.g. back reflector materials such as Al, transparent conducting oxide materials such as indium tin oxide) in uniform thin film form.

Common prior art continuous web processes involve the transport of a horizontally oriented web substrate through a series of deposition chambers, each of which is used for the deposition of a layer of a particular composition within the stacked structure of a multilayer device. Layers are deposited on the web substrate as it passes from chamber to chamber. One disadvantage with deposition onto a horizontally oriented web is the accumulation of debris and unwanted reaction products on the substrate. Vacuum or low pressure deposition processes such as plasma enhanced chemical vapor deposition, glow discharge, and physical vapor deposition are most commonly used to prepare thin film layers of amorphous silicon. These processes generally produce unwanted side products that may settle on the web as it is transported horizontally. These unwanted products compromise the purity of individual layers and the device as a whole and generally lead to less than optimal final product devices. Also, debris and particles may be wound up in the rolls of continuous manufacturing processes and may damage deposited layers. Consequently, it is desirable to identify methods that minimize the formation of unwanted deposition products, methods that prevent such products from forming, depositing or falling on the web, or methods that allow the non-detrimental removal of such products between deposition chambers.

### SUMMARY OF THE INVENTION

Disclosed herein is a high throughput deposition apparatus for the production of multilayer thin film structures. The apparatus includes a series of one or more deposition chambers for the purpose of producing thin film layers of different composition and thickness. High throughput is achieved by transporting a plurality of discrete substrates or continuous webs, into the series of deposition chambers to achieve a parallel processing deposition capability. A layer of material is deposited on each substrate or web within the plurality in each deposition chamber. The conditions within each deposition chamber are substantially uniform across the plurality of substrates or webs so that substantially identical layers are deposited on each of the substrates or webs. The instant invention contemplates substrate or web transport in horizontal, vertical and other orientations relative to the deposition chambers and further provides for the deposition of a wide range of thin film layer compositions via a variety of deposition processes. Multilayer structures are achieved by transporting the plurality of substrates or continuous webs through a series of deposition chambers, each of which is operated independently of the others according to a particular deposition technique at conditions required to form a layer of desired composition and thickness. Layer integrity is maintained by isolating the deposition chambers from each other.

In a preferred embodiment herein, multilayer semiconductor structures are prepared in a series of two or more operatively connected deposition chambers through a plasma enhanced chemical vapor deposition process; for example, a glow discharge process. In another preferred embodiment, deposition chambers utilizing different deposition techniques are included in the instant deposition apparatus. Deposition chambers utilizing plasma enhanced chemical vapor deposition in combination with deposition chambers utilizing sputtering constitute one preferred embodiment of the instant deposition apparatus. Some preferred structures include layers of amorphous, microcrystalline or polycrystalline silicon that are n-type, p-type or intrinsic deposited on a steel substrate. Some preferred structures include a back reflecting or transparent conducting oxide layer in combination with one or more silicon containing layers on a substrate or continuous web. A vertical orientation of two pluralities of parallel continuous webs disposed on opposite sides of a vertically situated cathode is a preferred configuration to maximize throughput. The substrates or continuous webs may be stainless steel. Delivery and extraction of the substrates or webs from the deposition chambers may be accomplished by independent payout and take-up units.

Also disclosed herein is a notched web supporter that facilitates transport of substrates or continuous webs within the instant deposition apparatus. The instant web supporter guides or tracks a substrate or continuous web without damaging the deposition surface or the integrity of films that may have been deposited on the substrate or continuous web. In a preferred embodiment, the instant web supporter facilitates horizontal transport of a vertically oriented substrate or continuous web. In a particularly preferred embodiment, the instant web supporter includes flexible displacement means to compensate and dampen fluctuations in the position of a substrate or continuous web during its transport.

### BRIEF DESCRIPTION OF THE DRAWINGS

FIG. 1A. Schematic depiction of a deposition apparatus according to the instant invention.

FIG. 1B. Top view of the pay out unit of the apparatus depicted in FIG. 1A.

FIG. 1C. Side view of the apparatus depicted in FIG. 1A.

FIG. 2A. A web supporter having a central notch and flexible displacement means.

FIG. 2B. End view of the web supporter depicted in FIG. 2A.

### DETAILED DESCRIPTION

The instant invention provides a high throughput parallel processing deposition apparatus capable of producing multilayer thin film structures. The deposition apparatus includes a pay-out unit for providing a plurality of substrates or continuous webs, a deposition unit in which one or more thin films is deposited on the substrates or continuous webs in one or more deposition chambers utilizing one or more deposition techniques, and a take-up unit for receiving the substrates or continuous webs after deposition. As used herein, the terms “parallel deposition” or “parallel processing” refer to substantially simultaneous deposition on a plurality of substrates or continuous webs or portions thereof that are transported simultaneously into and through the deposition unit. High throughput is achieved in the instant deposition apparatus by delivering a plurality of substrates or continuous webs to the deposition unit whereby deposition occurs substantially simultaneously on all substrates or webs. The deposition unit comprises one or a series of operatively connected deposition chambers wherein the conditions of each deposition chamber are established for the purpose of depositing a thin film layer with an intended composition and thickness for a given web transport speed. Deposition chambers utilizing different deposition techniques may also be included in the instant deposition unit. By transporting the substrates or continuous webs through a series of chambers, multilayer structures comprising layers of variable composition and thickness may be achieved simultaneously on a plurality of substrates or continuous webs.

Discrete or continuous substrates may be used in the instant apparatus. A continuous substrate is a web substrate having an extended length in the direction of transport within the deposition apparatus and shall hereinafter be referred to as a “continuous web”, “web”, “continuous web substrate”, “web substrate” or the like. In a preferred embodiment, a continuous web extends at least a distance in one dimension corresponding to the distance between the pay-out and take-up units of the instant apparatus. In a particularly preferred embodiment, the length of a continuous web is substantially longer than the distance between the pay-out and take-up units.

A discrete substrate is a substrate that is not continuous. A discrete substrate may be obtained, for example, by sub-dividing a continuous substrate along its longest dimensions into a series of several pieces. In a preferred embodiment, the length of a discrete substrate is such that the substrate fits in its entirety within the deposition chamber of the instant apparatus. In a particularly preferred embodiment, thin film layer deposition is accomplished through plasma enhanced chemical vapor deposition method that utilizes a cathode and the size of a discrete substrate is such that the cathode is able to deposit a thin film layer on substantially the entire deposition surface of substrate when the substrate is stationarily positioned before the cathode. Generally, this particularly preferred embodiment implies that the deposition surface of a discrete substrate is smaller than or approximately equal to the size of the active surface of the instant cathode where the active surface is the cathode surface that forms a boundary for the plasma. A plurality of discrete substrates may be introduced in such a way that each substrate within the plurality is independently introduced into the instant apparatus or in such a way that one or more substrates within the plurality are jointly introduced into the instant apparatus. Discrete substrates may also be positioned on a continuous surface and transported thereon through the instant apparatus. Various manners of introducing discrete substrates have been contemplated in U.S. Pat. No. 4,423,701 of the instant assignee, the disclosure of which is hereby incorporated by reference.

The instant invention further contemplates the introduction of a plurality of discrete substrates where each substrate within the plurality is disposed on the same side of a cathode in an embodiment in which thin film layer deposition occurs through a plasma enhanced chemical vapor deposition process. The instant invention similarly contemplates the introduction of a plurality of continuous web substrates where each member of the plurality is disposed on the same side of a cathode in an embodiment in which thin film layer deposition occurs through a plasma enhanced chemical vapor deposition process. These embodiments provide for improved throughput relative to the prior art. The embodiments are possible because the instant inventors have invented a deposition apparatus in which deposition conditions can be maintained in a substantially uniform fashion across each of a plurality of continuous web or discrete substrates. By doing so, the instant inventors have addressed an outstanding problem in the art. Uniform deposition conditions provide for the deposition of thin film layers that are substantially uniform in composition and thickness on a plurality of substrates maintained for a particular amount of time in the deposition chamber. As described hereinbelow, time of contact or transport speed through the instant deposition apparatus may be used to vary the composition and/or thickness of deposited thin film layers.

Much of the discussion hereinbelow describes the instant apparatus in the context of continuous web substrates. It is to be recognized, however, that the discussion applies equally well, with only obvious modification, to embodiments utilizing discrete substrates.

In a preferred embodiment, a co-planar plurality of continuous webs is provided by the payout unit. As used herein, the terms “co-planar plurality of continuous webs”, “co-planar plurality of webs”, “co-planar webs” and the like refer to two or more webs that have deposition surfaces that reside substantially in a common plane during transport through the deposition unit. In a particularly preferred embodiment, a co-planar plurality of webs is parallel in the sense that the webs within the co-planar plurality of webs are aligned, spatially separated, but transported in the same direction through the instant deposition unit. Analogous embodiments apply to discrete substrates.

In some embodiments herein, more than one co-planar plurality of continuous webs is included. The terms “co-planar pluralities of continuous webs”, “co-planar pluralities of webs”, “sets of co-planar webs” and the like are used to refer to situations in which more than one coplanar plurality of webs is used. If two co-planar pluralities of webs are used, for example, each plurality comprises two or more webs positioned with their deposition surfaces in a common plane where each plurality resides in a different plane. The two planes may be oriented in any manner relative to each other. The description is analogously extended to situations in which more than two co-planar pluralities of webs are used. One or more co-planar pluralities may also be used in combination with a single web. Analogous embodiments apply to discrete substrates.

Embodiments in which a plurality of non-co-planar webs is used also fall within the scope of the instant invention. As used herein, the terms “plurality of non-co-planar webs”, “non-coplanar webs” and the like refer to two or more webs that are positioned such that their deposition surfaces do not reside in a common plane. Non-co-planar webs may, for example, have deposition surfaces that are staggered, rotated or otherwise displaced relative to each other. In plasma enhanced chemical vapor deposition, for example, one example of a non-co-planar plurality of webs is the situation in which each of two webs is parallel to a planar cathode, but located at different distances therefrom. Since proximity to the cathode influences the thickness, composition, and other properties of a thin film layer, non-co-planar webs may provide for the simultaneous deposition of non-identical thin film layers. Non-co-planar webs may also be parallel. Parallel non-co-planar webs are non-co-planar webs whose deposition surfaces are parallel to a common reference plane (e.g. a planar cathode surface) and whose directions of transport are the same. Embodiments including non-co-planar webs are generally less preferred because it may be more difficult to maintain uniform deposition conditions.

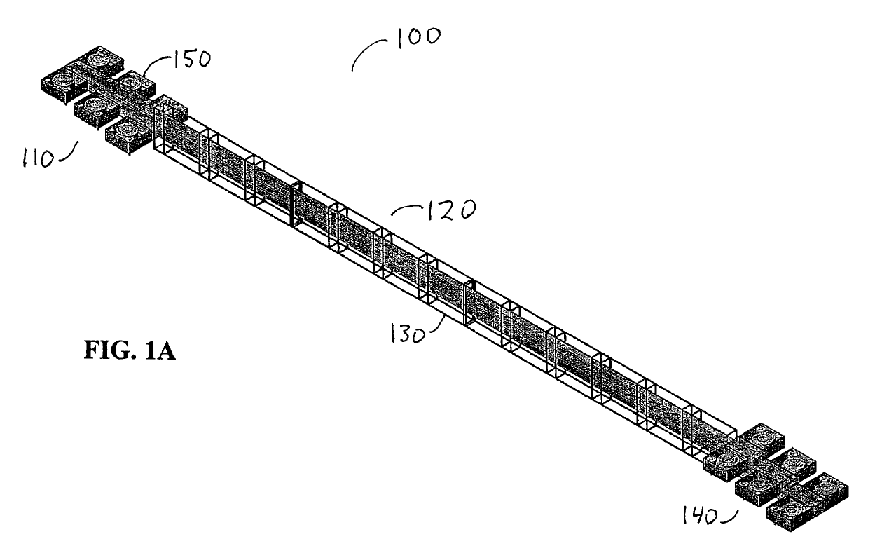

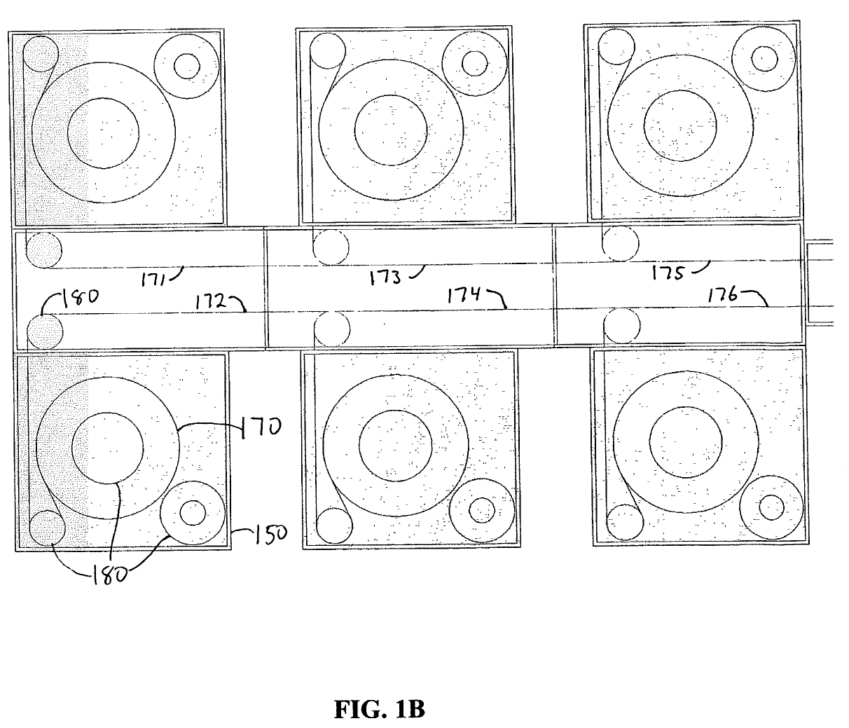

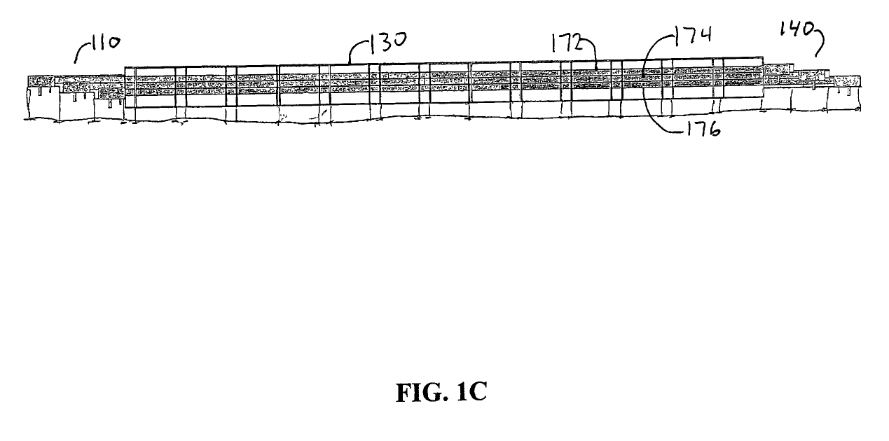

Referring now to FIG. 1A, there is disclosed a schematic depiction of a preferred embodiment of the deposition apparatus. The apparatus 100 includes a pay-out unit 110, a deposition unit 120 comprising a series of one or more deposition chambers 130, and a take up unit 140. The pay-out unit dispenses one or more pluralities of continuous web substrates from one or more dispensers 150. The dispensing of webs may be accomplished, for example, by loading a coiled band of web substrate material on a pay-out roller and turning the roller to deliver the web substrate to the series of one or more deposition chambers. A plurality of webs can be delivered by loading and dispensing two or more coiled web substrate bands on a single pay-out roller or by providing a separate pay-out roller for each web within a plurality of webs. By appropriately positioning rollers or other dispensation means, co-planar, non-co-planar and parallel pluralities of webs may be provided. Two or more pluralities of webs may be similarly delivered by appropriately positioning the pay-out rollers or dispensation means associated with each plurality. It is further possible in plasma enhanced chemical vapor deposition to dispense two or more pluralities of webs on different sides of a cathode so that the cathode is interposed between at least two webs within the two or more pluralities of webs.

In the embodiment of FIG. 1A, the pay out unit provides six webs 171, 172, 173, 174, 175, 176 and each web is provided by a separate dispenser 150. A top view of the pay out unit of the embodiment of FIG. 1A is shown in FIG. 1B herein. Each dispenser 150 includes a coil of web substrate material 170 and one or more rollers 180 for turning the coil and delivering the web substrate to the deposition unit 120 of FIG. 1A In the embodiment of FIG. 1A, as described further hereinbelow, the dispensers are positioned to deliver two sets of parallel webs, where each set includes three webs aligned in a common vertical plane. One set of three parallel webs is depicted in the side view representation shown in FIG. 1C of the embodiment of FIG. 1A. The pay out unit 110 and take up unit 140 are located as shown. The three parallel webs are shown at 172, 174, and 176. A second set of three parallel webs 171, 173, and 175 is positioned behind the webs 172, 174, and 176. The deposition chambers 130 of FIGS. 1A and 1C are shown in open view to facilitate viewing of the webs. The deposition chambers 130 are described more fully hereinbelow.

In addition to high throughput, the plurality of web substrates provided by the instant invention permits simultaneous deposition on substrates of different types or thicknesses. For example, parallel deposition may be accomplished on steel substrates of different thicknesses or on steel and a non-steel (e.g. plastic) substrate. When a plurality of pay-out rollers is used, the instant invention further provides for transport of web substrates at variable speeds. Separate pay-out rollers may be set to dispense at different speeds. Variable speeds permit the deposition of thin film layers of different thicknesses on different substrates in a deposition chamber operating at a fixed set of deposition conditions.

The take-up unit 140 depicted in the embodiment of FIG. 1A herein receives the plurality of webs from the deposition unit and stores them for post-deposition processing or delivery. The take-up unit is preferably similar in form and opposite i function in comparison to the pay-out unit in the sense that it receives rather than dispenses webs. The take-up unit may include one or more take-up rollers for receiving a plurality of webs upon conclusion of deposition. The take-up unit may include a single take-up roller adapted to receive a plurality of webs or several take-up rollers, each of which receives a single web, or a combination thereof. In a preferred embodiment, each of a plurality of webs is dispensed by a pay-out roller dedicated to that web and received by a take-up roller dedicated to that web with the web extending continuously from the pay-out roller to the take-up roller and the rollers being synchronized to maintain tautness in the web.

The relative positions of each of a plurality of webs may be variably determined by controlling the relative positions and orientations of the pay-out and take-up rollers. Co-planar webs disposed horizontally or vertically with variable spacings therebetween or directions of transport, for example, are achievable with the instant invention. A horizontal (vertical) co-planar plurality of webs is a co-planar plurality of webs that have deposition surfaces that reside in or are disposed in a common horizontal (vertical) plane. Orientation may also be used to refer to the state of disposition of a co-planar plurality of webs. A co-planar plurality of webs oriented horizontally (vertically) is a co-planar plurality whose deposition surfaces are disposed in a common horizontal (vertical) plane. Co-planar webs in a common non-horizontal or non-vertical plane are also achievable as are two or more co-planar pluralities of webs whose deposition surfaces are disposed in two or more planes. As described hereinabove, co-planar webs may also be parallel. In the embodiment of FIG. 1A herein, two co-planar pluralities of continuous webs, each of which comprises three parallel webs oriented vertically, are shown. A first plurality of three parallel webs is disposed in a first common vertical plane and a second plurality of three parallel webs is disposed in a second common vertical plane in the embodiment of FIG. 1A with a total throughput of six webs. In the embodiment of FIG. 1A, the cathodes that may be present in deposition unit 120 are interposed between the two pluralities of webs.

Upon dispensation from the pay-out unit, a plurality of webs enters the deposition unit and is transported therethrough toward the take-up unit. The deposition unit includes one or a series of operatively connected deposition chambers, each of which has conditions established for the deposition of a thin film layer of an intended composition and thickness for a given web transport speed. The deposition chambers within a series are isolated from each other to prevent cross-contamination and may utilize different deposition techniques. As a result, the formation of multilayer thin film structures comprising a plurality of thin film compositions and thicknesses are achievable with the instant deposition apparatus. As indicated hereinabove, film thickness is also influenced by the web transport speed with slower speeds generally providing thicker films. Depending on the rate of thin film layer formation and the kinetics of the physical and/or chemical processes associated with deposition, layer composition may also depend on web transport speed.

A variety of thin film deposition methods may be used in the instant deposition apparatus. Methods including chemical vapor deposition, physical vapor deposition, sputtering, and vacuum deposition are within the scope of the instant invention. In one preferred embodiment, deposition is accomplished through plasma enhanced chemical vapor deposition (PECVD). PECVD deposition refers to a plasma assisted deposition process. Glow discharge is one example of a plasma assisted deposition process. In PECVD deposition, a plasma is created in a deposition chamber in a plasma region between a grounded web or substrate and a cathode positioned in close proximity to the web or substrate. The plasma region represents the region in space in which a plasma may be formed. When a plurality of webs or substrates is utilized, the plasma region preferably extends over each web or substrate within the plurality.

In a preferred embodiment, the cathode surfaces are substantially planar and rectangular in shape. In a typical configuration, the cathode is connected to an electrical power supply that provides the electrical or electromagnetic energy necessary to establish and maintain a plasma in the plasma region between the cathode and deposition surfaces of continuous webs or discrete substrates. The power supply may be an AC power supply that introduces AC energy in the radiofrequency or microwave range, but may also be a DC power supply. In a preferred embodiment, an AC power supply operating at 13.56 MHz is used. VHF frequencies (for example, 70 MHz) and microwave frequencies (for example, 2.54 GHz) are within the scope of the instant invention.

The plasma is created from process gases that enter the plasma region between the cathode and webs or substrates while the power supply is operating or while electromagnetic energy is otherwise being introduced to the plasma region. Process gases include deposition precursors, the feed gases that react or are otherwise transformed into the reactive species required to form a film on a deposition surface during PECVD processing. When depositing amorphous, microcrystalline or polycrystalline silicon, for example, deposition precursors such as silane (SiH₄), disilane (Si₂H₆), SiF₄, or (CH₃)₂SiCl₂ may be used. Gerniane may also be used as a deposition precursor to form germanium films or in combination with a silicon deposition precursor to form silicon-germanium alloys. Deposition precursors such as methane (CH₄) and CO₂ are carbon sources and may be used, for example, in combination with a silicon deposition precursor to form SiC or other carbon containing films. Deposition precursors may also include doping precursors such as phosphine, diborane, or BF₃ for n or p type doping. Process gases may also include carrier gases, such as inert or diluent gases, including hydrogen, which may or may not be incorporated in a deposited thin film.

During PECVD processing, the reactive species deposit on the web or substrate to provide material used to form a layer. PECVD deposition and processing can occur with a single processing gas or deposition precursor or with a plurality of processing gases or deposition precursors, depending on the intended composition, thickness and/or growth mechanism of the deposited thin film. Process gases may be introduced via valves and gas lines connected to the deposition unit or chamber and may also be introduced through openings within the cathode. The delivery of process gases may also occur through the cathode as described in U.S. patent application Ser. No. 10/043,010 entitled “Fountain Cathode for Large Area Plasma Deposition” assigned to the instant assignee, the disclosure of which is hereby incorporated by reference. In one embodiment, a gas manifold is used to provide process gases. The isolation of deposition chambers to minimize cross-contamination may be accomplished, for example, as described in U.S. Pat. No. 5,374,313 to the instant assignee; the disclosure of which is also hereby incorporated by reference.

Examples of plasma assisted deposition onto a web substrate are described in U.S. Pat. Nos. 4,485,125 and 4,423,701 to the instant assignee, the disclosures of which are hereby incorporated by reference. U.S. Pat. No. 4,485,125 discloses a multiple chamber apparatus for the continuous production of tandem, amorphous, photovoltaic cells on a web substrate using a plasma deposition method. In contrast to the instant apparatus, the apparatus of U.S. Pat. No. 4,485,125 describes deposition of thin film layers on a single continuous web and therefore offers lower processing throughput. U.S. Pat. No. 4,423,701 discloses a multiple chamber glow discharge apparatus having a non-horizontally disposed cathode for the deposition of thin film layers onto discrete plate or continuous web substrates. U.S. Pat. No. 4,423,701 further discloses deposition onto two continuous web substrates in which the two webs are disposed on opposite sides of a cathode. In contrast to the instant deposition apparatus, however, U.S. Pat. No. 4,423,701 does not describe co-planar continuous webs or a plurality of continuous webs disposed on the same side of a cathode. U.S. Pat. Nos. 4,423,701 and 4,485,125 also fail to demonstrate uniformity of deposition conditions across a plurality of webs or substrates disposed on the same side of a cathode.

In a preferred embodiment, a parallel co-planar plurality of webs is transported through the deposition unit. In a particularly preferred embodiment, the common plane in which the parallel co-planar plurality of webs is disposed is parallel to a planar cathode surface. In this embodiment, a plasma is developed between parallel surfaces (the cathode surface and the deposition surfaces of the parallel co-planar plurality of webs). This configuration is desirable because it facilitates the maintaining of uniform deposition conditions and promotes the formation of substantially uniform and identical thin film layers across a plurality of substrates. Consequently, reproducible growth is more easily achieved.

In another particularly preferred embodiment, PECVD deposition occurs on two parallel coplanar pluralities of continuous web substrates wherein each plurality of webs is disposed on a different side of a cathode. The cathode in such an embodiment may be interposed between the two parallel co-planar pluralities of webs. By interposing a cathode between two parallel coplanar pluralities of webs, it becomes possible to effect deposition on two sides of a cathode and thereby increase throughput. One set of parallel webs, for example, may be disposed on one side of a planar cathode with a second set of parallel webs being disposed on the opposite side of the same planar cathode. This embodiment is particularly preferred because it provides higher processing throughput while maintaining substantially uniform deposition conditions over a large number of webs. In this embodiment, plasma regions are formed between the cathode and both sets of oppositely disposed parallel webs. If, for example, a rectangular cathode shape is employed, two pluralities of parallel co-planar webs may be situated on opposite sides thereof to produce a configuration in which the cathode is interposed between the two pluralities. In this configuration, plasma regions may be formed between a first rectangular surface of the cathode and a first set of parallel webs as well as between a second rectangular surface of the cathode and a second set of parallel webs. Each set of webs comprises a plurality of continuous web substrates. In the embodiment of FIG. 1A herein, two sets of three parallel webs are shown. One set of webs is positioned on one side of a rectangular cathode and a second set of webs is positioned on the opposite side of the rectangular cathode. The advantage of this configuration is that one cathode may be used to simultaneously deposit thin film layers in more than one direction through the creation of plasma regions extending from two or more cathode surfaces.

As described hereinabove, a co-planar plurality of webs may be oriented horizontally, vertically, non-horizontally, or non-vertically. In a preferred embodiment in which PECVD deposition is used, the cathode and one or more pluralities of co-planar webs are oriented substantially identically. Thus, if a vertical cathode is employed, each plurality of webs is preferably oriented substantially vertically. If two pluralities of co-planar webs are used in conjunction with a vertical cathode, for example, one plurality of co-planar webs may be positioned vertically to the left of the cathode and another plurality of co-planar webs may be positioned vertically to the right of the cathode. The cathode is thus interposed between the two co-planar pluralities of webs. Similarly, if a horizontal cathode is employed, one plurality of webs may be positioned horizontally above the cathode and another plurality of webs may be positioned horizontally below the cathode so that the cathode is interposed between the two coplanar pluralities of webs. Two or more pluralities of continuous webs may also be disposed on the same side of a cathode so that the cathode is not interposed therebetween.

Thin film layers with a variety of compositions, properties and thicknesses ranging from tens of angstroms to a few thousand angstroms are achievable with the instant deposition apparatus. The ability to include deposition chambers within the instant deposition apparatus that utilize different deposition techniques affords tremendous flexibility in controlling the composition and properties of deposited films. Conducting, semiconducting, and non-conducting thin film layers, for example, may be formed in the deposition unit of the instant invention. In a preferred embodiment, thin film layers including silicon are formed in deposition chambers utilizing PECVD deposition. The amorphous, polycrystalline and microcrystalline phases of silicon may be formed in the instant deposition apparatus. N-type, i-type (intrinsic), and p-type forms of silicon may also be formed as can alloys of silicon and germanium. SiC and SiO may also be formed.

By utilizing a deposition technique such as sputtering in one or more deposition chambers, it is also possible to form other types of thin film layers such as back reflector layers and transparent conducting oxide layers. Examples of back reflector layers and transparent conducting oxide layers are presented hereinbelow. Sputtering is a process in which a solid target that contains or is otherwise capable of forming an intended thin film composition is ablated by bombardment with energetic ions from a low pressure plasma struck in a gas. Ejected material from the target, typically in the form of ionized atoms or clusters, passes to a substrate or continuous web where a sputtered film of or from the target material is formed. Generally, the sputtered film has a chemical composition that matches or is similar to that of the target material. The sputtering of an Ag target, for example, produces an Ag sputtered film. The plasma may be formed from a chemically inert gas such as Ar, a reactive gas such as O₂ or H₂, or a combination of inert and reactive gases. When a reactive gas is used, the sputtered film may include a chemical compound formed from a reaction of the target material and reactive gas. ZnO, for example, may be formed by sputtering a Zn target in the presence of O₂. A deposition chamber that utilizes sputtering as the deposition technique may hereafter be referred to as a sputtering chamber. A sputtering chamber includes a target and means for sputtering the target to form a sputtered thin film on a substrate or continuous web. The sputtering means includes means for forming a plasma between the target and substrate or web from a chemically inert or reactive gas introduced into the sputtering chamber. Plasma formation may be accomplished in the manner described hereinabove in the context of the PECVD deposition technique.

The thicknesses of the thin film layers formed by the instant deposition apparatus may be controlled by controlling the conditions within the deposition chambers of the instant deposition apparatus or by controlling the speed of web transport. Relevant experimental variables depend on the selected method of deposition. During PECVD film formation, for example, factors such as the flow rates of process gases, deposition precursors or doping precursors; temperature of deposition; distance between webs or substrates and cathode; and plasma strength may influence the rate of film formation and the thickness of the resulting film at a particular web transport speed. For a particular set of deposition conditions, the web transport speed or substrate exposure time may also influence thin film thickness. Slower transport speeds imply that a web resides in the plasma region for a longer time and this generally leads to thicker films. During a sputtering process, for example, factors such as the applied voltage, target composition, target location and chamber pressure may influence the rate of film formation. Thin films with thicknesses ranging from tens of angstroms to thousands of angstroms are achievable with the instant deposition apparatus.

By including a plurality of deposition chambers that may utilize different deposition techniques in the instant deposition unit, it is possible to form multilayer thin film structures in which a plurality of thin film layers with a range of compositions and/or thicknesses are deposited on continuous webs or substrates. As used herein, the terms “a thin film layer deposited on a web substrate”, “a thin film layer formed on a continuous web”, “a thin film present on a web” and equivalents thereof as well as equivalents thereof for discrete substrates refer to a thin film layer supported by a web or substrate and may or may not mean that the film is in physical contact with the web or substrate. The first layer formed in the deposition unit is in physical contact with the web or substrate. If a plurality of deposition chambers is included in the deposition unit, additional layers may be formed. These additional layers may be formed directly over thin film layers that have been formed in preceding deposition chambers and may lack direct physical contact with a web or substrate. Nonetheless such films shall be referred to herein as being on the web or substrate since they are supported by the web or substrate. All of the layers of a sequential multilayer structure, for example, in which the layers ascend away from the web or substrate are referred to herein as being on the web or substrate even when not all of the layers are in physical contact with the web or substrate.

Multilayer structures such as those required for photovoltaic devices, solar cells, p-n junctions or nip structures may be deposited on a plurality of continuous webs or substrates with the instant deposition apparatus. An nip structure may be deposited, for example, in a deposition unit that includes three deposition chambers in which an n-type thin film layer is formed in a first deposition chamber, an i-type layer is formed in a second deposition chamber, and a p-type layer is formed in a third deposition chamber. Tandem devices, such as triple cells, may also be readily formed in the instant deposition unit. In addition to conductivity type, multilayer structures that include thin film layers of different phases are also within the scope of the instant deposition apparatus. Multilayer structures, for example, that include amorphous thin film layers in the presence of microcrystalline or polycrystalline thin film layers may be deposited with the instant invention. Thin film structures that include back reflector or transparent conducting oxide layers may also be formed. An important aspect of the instant invention is that both single layer and multilayer structures may be deposited over a plurality of webs in a uniform, reproducible and consistent fashion.

One example of a multilayer structure that may be formed with the instant deposition apparatus is now described. An nip structure may be formed, for example by depositing a n-type layer on a stainless steel web, subsequently forming an i-type layer on the n-type layer, and finally forming a p-type layer on the i-type layer. The n-type layer may, for example, be an amorphous silicon layer doped with boron having a thickness of 200 angstroms. The i-type layer may, for example, be amorphous silicon or an alloy of silicon and germanium having a thickness of 800 angstrom. The p-type layer may be microcrystalline silicon doped with phosphorous having a thickness of 250 angstroms. Similarly, tandem devices containing a plurality of nip structures may be formed where, if desired, the thickness and/or composition of each type of layer may be varied. Triple cells including i-type layers having different compositions (e.g. different alloys of silicon and germanium) and different bandgaps, for example, may be formed. Similarly, n-type layers that are microcrystalline or p-type layers that are amorphous are among the layers that may be formed. Composite layers such as an n-type layer that includes an amorphous sub-layer and a microcrystalline sub-layer are also possible. Structures including back reflector layers or transparent conducting oxide layers may also be formed. Representative back reflector layer materials include but are not limited to ZnO, Ag, Ag/ZnO combination, Al, and Al/ZnO combination. Representative transparent conducting oxide layer materials include but are not limited to ZnO, ITO (InSnO₂), and SnO. In a preferred embodiment, back reflector and transparent conducting oxide layers are deposited in deposition chambers within the instant deposition unit that utilize a sputtering process and appropriate targets.

Uniform deposition of thin film layers is best accomplished on continuous webs that are transported continuously and uniformly through the deposition apparatus. For attainment of thin film layers with uniform thicknesses and compositions, web transport preferably occurs uninterrupted at a uniform speed. Each web within a plurality of webs is preferably transported at a uniform speed, but the transport speed of one of a plurality of webs may or may not be identical to the transport speed of other webs within the plurality of webs. Interruptions in transport cause undesired variations in transport speed and may lead to non-uniformities in layer thickness or composition. Interruptions are therefore generally detrimental when uniform layers are desired. Examples of interruptions include stoppages, pauses, hesitation or jerkiness in web transport.

The direction of transport of a web is another consideration within the scope of the instant deposition apparatus. The direction of transport refers to the direction of motion of a web as it passes through the instant deposition unit and is a consideration in addition to the direction of orientation of a web or plurality of webs. Horizontal web transport, for example, refers to horizontal motion of a web through a deposition unit and may occur with horizontally or vertically oriented webs. Similarly, vertical web transport refers to vertical motion of a web through a deposition unit and may occur with horizontally or vertically oriented webs. A horizontal direction of transport, for example, may be thought of as motion parallel to the ground and a vertical direction of transport, for example, may be thought of as motion perpendicular to the ground.

Generally, transport of horizontally oriented webs is more easily made uniform than transport of non-horizontally or vertically oriented webs. Webs are generally several inches wide, several to hundreds or even thousands of feet long, and only a fraction of an inch thick. A web 14 inches wide, a mile long and 5 mils thick, for example, may be used in the instant deposition apparatus. As indicated hereinabove, horizontally (vertically) oriented webs are webs whose deposition surfaces are disposed in a horizontal (vertical) plane. In the transport of horizontally oriented webs, a large surface area surface of the web is generally in contact with a transporting device or mechanism such rollers distributed within the deposition apparatus. A large surface area of contact distributes the weight of the web over a larger area and facilitates achievement of uniform web transport. Uniform transport of vertically oriented webs is more difficult to achieve because the web may be situated on an edge with the weight of the web being concentrated over a small surface area. Such a situation occurs, for example, when a vertically oriented web is transported in a horizontal direction. Complications such as pinching during transport of vertically oriented webs may become problematic. Vertical orientation of a web that extends over large distances may also present problems with sagging or buckling. As a result, it is more difficult to balance and uniformly transport vertically oriented webs.

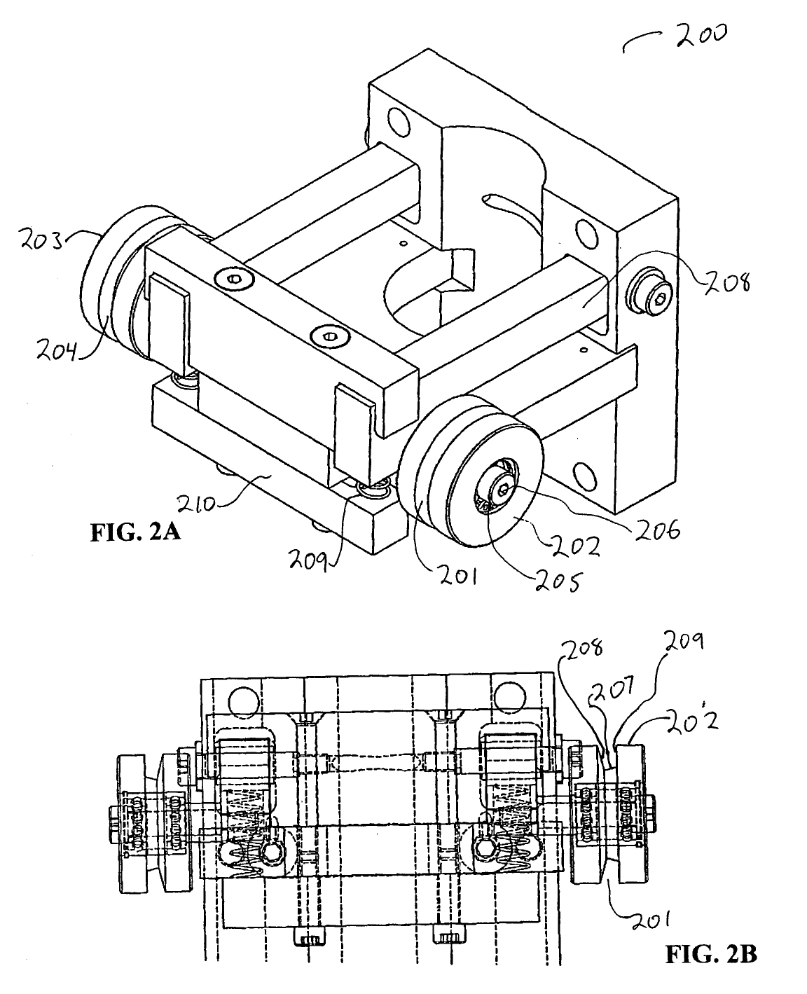

The instant inventors have invented a web supporter to facilitate uniform transport of webs in a continuous deposition apparatus. In a preferred embodiment, the instant web supporter is used to facilitate uniform horizontal transport of vertically oriented webs. The instant web supporter is schematically illustrated in FIG. 2A herein along with representative mounting hardware at 200. The supporter 202 is generally circular in shape and features a central notch 201 that is aligned with the direction of web transport when the supporter is installed in a deposition apparatus. The mounting hardware shown in the embodiment of FIG. 2A provides for inclusion of a second supporter 203 having a central notch 204 oppositely disposed from supporter 202. The web supporters 202 and 203 may be used to support spatially separated, substantially parallel webs. In a preferred embodiment, a cathode is located in a plane midway between the planes defined by webs supported by web supporters 202 and 203 so that film deposition may occur on webs supported by web supporters 202 and 203 at the same time. A bearing assembly 205 may be included to facilitate rotation of the web supporter 202 about an axle 206.

FIG. 2B shows the web supporter 202 as viewed along the direction of web transport. The central notch 201 includes a recessed region in which a substrate or continuous web may be inserted and contributes to the stabilization of the motion of the substrate or web. Central notch 201 includes a lower support surface 207, an inside notch surface 208 and an outside notch surface 209. A web inserted into the central notch is preferably supported primarily by lower support surface 207. Insertion of the web occurs normal to the plane of FIG. 2B with the edge of the web contacting lower support surface 207. Generally, the deposition surface of the web faces inside notch surface 208.

An important requirement for substrate or web transport in a deposition apparatus is prevention of scratching, gouging or otherwise damaging the thin film layers that have been deposited on the deposition surface of the web. The prevention of damage requires eliminating the possibility of physical contact of the thin films with the web supporter or other transport means. In the instant web supporter, physical contact of the thin film side of the web with the web supporter may be excluded by forming a central notch that biases the position of the web away from either or both of the inside and outside notch surfaces.

An example of a lower support surface that biases the position of an inserted web away from the inside and outside notch surfaces is shown in the embodiment of FIG. 2B herein. In the embodiment of FIG. 2B herein, the lower support surface 207 of the central notch 201 is angled so that an inserted web is biased away from inside notch surface 208 and outside notch surface 209. In the embodiment of FIG. 2B herein, if the notch is wider than the web is thick, the biasing due to the angled lower support surface 207 results in a positioning of the web in which a gap is present between the surfaces of the web and inside and outside notch surfaces 208 and 209. The sloping of inside notch surface 208 further facilitates gap formation on one side of the web. The gaps preclude physical contact of the deposition surface of the web and any thin films deposited thereon as well as the opposing web surface with the instant web supporter. Damage to deposited thin films is thereby avoided as is damage to the opposing web surface. Avoidance of physical contact is also desirable for smooth web transport.

While the embodiment of FIG. 2B herein depicts one example of a notch within the scope of the instant invention, it is evident that any notch shape capable of creating a gap between a surface of the web supporter and a surface of an inserted web may function to prevent physical contact between the instant web supporter and a surface of the web. Various shapes and configurations of the surfaces defining the notch may be envisioned. The notch depicted in the embodiment of FIG. 2B may be viewed as an asymmetric V-shaped notch. Other V-shaped notches, both symmetric and asymmetric, are included in the scope of the instant invention. A V-shaped notch that is wider than the web thickness may generally be used to support a web while preventing physical contact of a web surface with the web support. In the V-shaped embodiment, gaps may be formed between both surfaces of the web (the surface on which deposition occurs and the surface opposite thereto) and the web supporter. A U-shaped lower support surface may also be used. Thus, it is evident that both symmetric and asymmetric notch shapes may be used to achieve web transport without damaging deposited thin films.

In a deposition apparatus intended for deposition onto vertically oriented webs transported in a horizontal direction, a series of web supporters may be installed horizontally; that is, along the direction of web transport, between the pay-out unit and the take-up unit. A plurality of web supporters may thus be used to support a web as it is transported through a series of deposition chambers. The number of web supporters and the spacings therebetween are variable and may depend on factors such as the transport speed, weight of web and distance between the pay-out and take-up units. Each web within a parallel plurality of webs preferably passes through a separate series of supporters. In one embodiment, a web supporter is provided near the entrance and exit to each deposition chamber included in a deposition apparatus. During deposition, a vertically oriented web may be dispensed from a pay-out unit and fed into a series of horizontally placed web supporters that have their central notches aligned in the direction of transport. In receiving the web, the supporters engage it. By engaging the web, the instant supporters facilitate its motion by guiding or tracking its motion in the direction of transport by way of the central notches. The instant web supporters may also provide support for the weight of the web. The bottom edge of a vertically oriented web is positioned within the notches of the instant supporters. The notches act to guide a vertically oriented web as it passes through the deposition apparatus in a horizontal direction of transport. The series of central notches present in a series of horizontally aligned web supporters creates a channel through which a vertical web passes as it is transported horizontally through the deposition apparatus. The central notches provide for substantially unidirectional transport of a vertical web and act to track the web. The central notches minimize motional jitter in directions lateral to the transport direction and stabilize vertical web transport to provide uniformity in transport throughout the deposition apparatus. The central notches may also be beneficial for non-horizontal directions of transport when it is desired to support or direct one or more webs along an edge.

The instant supporters further facilitate transport by rotating in the direction of web transport as the web passes over them so that the supporters rotatably engage a continuous web as it passes through a deposition apparatus. The supporters are preferably mounted so that they freely rotate upon engaging a moving web. Rotation may occur, for example, about an axle such as the one shown at 206 in FIG. 2A, mounted perpendicular to the direction of web transport. Rotational motion is beneficial because it inhibits frictional resistance to the motion of the web. Complications such as binding or pinching of the web during transport are thereby minimized because web transport is facilitated through a rolling mechanism rather than a sliding mechanism.

Flexible displacement means may also be attached to the instant web supporters so that they may individually and independently adjust their position according to the supported weight. By way of illustration, the example of a vertically oriented web that is transported in a horizontal direction is considered. Optimally, the weight of such a vertical web is evenly distributed across all web supporters along its direction of transport. In this optimal situation, each web supporter in the series of web supporters may be at the same vertical position to maintain level transport of the web. If, however, the process of transporting the web leads to momentary or other motional disturbances that act to non-uniformly distribute the weight of the web, it is desirable to have a support mechanism that is responsive to and counteracts a changing web weight distribution to promote more uniform web transport. This responsiveness may be accomplished through the flexible mounting of the web supporters used to support a vertically oriented web. Flexible mounting may be achieved by attaching flexible displacement means to the instant web supporters.

A spring mounting mechanism that permits the instant web supporters to adjust their vertical position up or down in response to changes in the weight distribution, for example, may be used as flexible displacement means. One example of flexible displacement means is included in FIG. 2A herein. In the embodiment of FIG. 2A herein, the axle 206 about which the web supporter 202 rotates, is mounted on displaceable arm 208 which is flexibly connected through spring means 209 to fixed support plate 210. Spring means 209 permits motion of web supporter 202 in response to displacements or motional disturbances of a web inserted in central notch 201. If a web supporter experiences an increase in the weight that it is required to support, a web supporter including flexible displacement means according to the embodiment of FIG. 2A may respond by lowering its vertical position through the contraction of spring means 209. The extent of the lowering of vertical position may be commensurate with the magnitude of the increased weight. A greater magnitude of increased weight implies a greater downward vertical lowering of the effected web supporter.

The net effect of this mechanism of vertical lowering of web supporter position through flexible displacement means is to counteract the motional disturbance of a web by redistributing weight to neighboring web supporters. This occurs because the web supporters most severely affected by a weight redistribution causing vertical lowering of its position due to a motional disturbance may lower to a greater extent than web supporters that are less severely affected. As a web supporter retracts to a position lower than its neighboring web supporters through the action of flexible displacement means such as the spring means depicted in the embodiment of FIG. 2A herein, the load thereon may be reduced and a commensurately greater load may be assumed by neighboring web supporters. Similarly, if the weight required to be supported by a web supporter is reduced due to a motional disturbance during web transport, a web supporter including flexible displacement means may respond by increasing its vertical height so that it assumes a greater relative load due to action of the flexible displacement means. An increase in vertical height may be achieved, for example, through the expansion of spring means 209 depicted in the embodiment of FIG. 2A herein.

Web supporters including flexible displacement means stabilize horizontal transport of a vertically oriented web by dampening fluctuations in weight distributions due to motional disturbances. Disturbances such as tilting, bobbing, twisting etc. of a web or irregularities in the pay-out or take-up of a web may produce fluctuations in web weight distribution across the length of the deposition apparatus. These fluctuations are counteracted and evened out through the redistributions that accompany the flexible upward and downward motion of the instant web supporters. As a result, horizontal transport of vertical webs occurs more evenly and uniformly with less binding and hesitation.

Although the instant web supporters are preferably used to facilitate the horizontal transport of vertically oriented continuous webs, they may also be used to aid non-horizontal web transport and the transported of non-vertically oriented webs. The instant web supporters provide two general functions. First, they may support the weight of a continuous web as it is transported through a deposition chamber. Second, they may guide or track the motion of a continuous web as it is transported through a deposition chamber. In embodiments involving non-vertically oriented webs or non-horizontally transported webs, the two functions of the web supporters may still be applicable to differing degrees of relevance. In the horizontal transport of a horizontally oriented continuous web, for example, the instant web supporters would likely not be used to substantially support the weight of the web, but may still be used at the edges of the web to track or guide the web. In such an embodiment, the web supporters may be oriented in a horizontal fashion in such a way that the central notches fit over the edges of the web. The web supporters may also rotate to increase the ease of motion of the web. The instant web supporters may similarly be used to guide or track the motion of vertically oriented webs that are transported in a vertical direction. In embodiments involving non-vertical, non-horizontal webs or directions of transport, the web supporters may provide some amount of support of the webs in combination with a guiding or tracking function.

A wide range of flexible displacement means known in the art may be employed in accordance with the instant invention. Flexible displacement means generally include an ability to reversibly change the position of the instant web supporter in response to disturbances in the motion of a web. Springs, coils, stretchable materials, compressible materials, materials that at least partially return to their initial shape or position upon displacement due to tension or compression, adjustable spacers etc. are examples of flexible displacement means.

The web supporter embodiments described hereinabove include a circular central notch having continuous inside and outside notch surfaces. Other embodiments that include discontinuous support surfaces also fall within the scope of the instant invention. Consider as an example a gear. The outer radial portion of a gear includes a plurality of cogs separated by gaps to form what may be referred to as a toothlike structure. Next consider the structure that results when grooves are cut in the cogs where the cutting direction is in the central plane of the gear. In such a structure, each cog has a separate notch where the set of all notches are aligned in the direction of rotation of the gear. Such a structure may also be used as a web supporter according to the instant invention where the set of individual notches functions analogous to the continuous central notch described hereinabove. Since the individual notches in such a structure are spatially separated, continuous inside and outside notch surfaces are not present. Instead, such a structure may be viewed as a central notch having discontinuous inside and outside notch surfaces. Since the number of grooved cogs and the size of cogs may vary in such a structure, it is evident that a number of embodiments of the web supporters having discontinuous inside and outside notch surfaces may be envisioned.

The foregoing drawings, discussion and descriptions are not intended to represent limitations upon the practice of the present invention, but rather are illustrative thereof. Numerous equivalents and variations of the foregoing embodiments are possible and intended to be within the scope of the instant invention. It is the following claims, including all equivalents, which define the scope of the invention.

We claim:

1. Apparatus for depositing a thin film layer on a co-planar plurality of continuous web substrates comprising:
a pay-out unit, said pay-out unit providing a co-planar plurality of continuous webs;
a deposition unit, said deposition unit receiving said co-planar continuous webs from said pay-out unit, said deposition unit including a deposition chamber, said deposition chamber including: a cathode; a plasma region between said cathode and said co-planar continuous webs; means for introducing electromagnetic energy into said plasma region; means for introducing process gases into said plasma region, said process gases including one or more deposition precursors, said one or more deposition precursors forming reactive species in said plasma region upon introduction of said electromagnetic energy, said reactive species forming a thin film layer on said co-planar continuous webs;
a take-up unit, said take-up unit receiving said co-planar continuous webs from said deposition unit.

2. The apparatus of claim 1, wherein said pay-out unit includes one or more rollers.

3. The apparatus of claim 2, wherein said pay-out unit includes separate rollers for each of said co-planar plurality of continuous webs.

4. The apparatus of claim 2, wherein said one or more of rollers provides said co-planar plurality of continuous webs at two or more speeds.

5. The apparatus of claim 1, wherein said co-planar plurality of continuous webs includes webs of different thicknesses.

6. The apparatus of claim 1, wherein said co-planar plurality of continuous webs includes webs of different composition.

7. The apparatus of claim 1, wherein said co-planar plurality of continuous webs comprises at least three webs.

8. The apparatus of claim 1, wherein said co-planar plurality of continuous webs comprises parallel webs.

9. The apparatus of claim 1, wherein said co-planar plurality of continuous webs is vertically oriented.

10. The apparatus of claim 9, wherein said vertically oriented webs are transported horizontally.

11. The apparatus of claim 1, wherein said cathode is vertically oriented.

12. The apparatus of claim 1, wherein a surface of said cathode and the plane in which the deposition surfaces of said co-planar plurality of webs reside are parallel to each other.

13. The apparatus of claim 1, wherein said electromagnetic energy is AC energy.

14. The apparatus of claim 13, wherein said AC energy is radiofrequency or microwave energy.

15. The apparatus of claim 1, wherein said process gases include a carrier gas.

16. The apparatus of claim 1, wherein said one or more deposition precursors includes a compound selected from the group consisting of silane, disilane, germane, methane, carbon dioxide, and (CH₃)₂SiCl₂.

17. The apparatus of claim 1, wherein said one or more deposition precursors include a doping precursor, said doping precursor providing an n-type or p-type dopant to said thin film layer.

18. The apparatus of claim 17, wherein said doping precursor is selected from the group consisting of phosphine, BF₃ and diborane.

19. The apparatus of claim 1, wherein said thin film layer comprises silicon or germanium.

20. The apparatus of claim 1, wherein said thin film layer comprises carbon.

21. The apparatus of claim 19, wherein said thin film layer further comprises oxygen.

22. The apparatus of claim 1, wherein said thin film layer is amorphous, microcrystalline or polycrystalline.

23. The apparatus of claim 1, wherein said thin film layer comprises a semiconductor.

24. The apparatus of claim 23, wherein said semiconductor is n-type or p-type.

25. The apparatus of claim 1, wherein said deposition unit includes a plurality of said deposition chambers, said plurality of deposition chambers forming a plurality of thin film layers on said webs.

26. The apparatus of claim 25, wherein said plurality of thin film layers includes layers with at least two compositions.

27. The apparatus of claim 25, wherein said plurality of thin film layers includes layers with at least two thicknesses.

28. The apparatus of claim 25, wherein said plurality of thin film layers includes an n-type semiconducting layer and a p-type semiconducting layer.

29. The apparatus of claim 28, wherein said plurality of thin film layers further includes an i-type semiconducting layer.

30. The apparatus of claim 29, wherein said i-type semiconducting layer is interposed between said n-type semiconducting layer and said p-type semiconducting layer.

31. The apparatus of claim 30, wherein said n-type semiconducting layer, said i-type semiconducting layer and said p-type semiconducting layer form a nip structure, said nip structure comprising an i-type semiconducting layer interposed between an n-type semiconducting layer and a p-type semiconducting layer, said i-type semiconducting layer being in physical contact with said n-type semiconducting layer and said p-type semiconducting layer.

32. The apparatus of claim 31, wherein said plurality of thin film layers includes a plurality of said nip structures.

33. The apparatus of claim 1, wherein said pay-out unit further provides one or more additional continuous webs.

34. The apparatus of claim 33, wherein said deposition chamber further includes: at least one additional plasma region between said cathode and said one or more additional continuous webs; means for introducing electromagnetic energy into said at least one additional plasma region; means for introducing said process gases into said at least one additional plasma region.

35. The apparatus of claim 33, wherein said one or more additional continuous webs includes at least two webs.

36. The apparatus of claim 35, wherein said at least two webs are co-planar.

37. The apparatus of claim 35, wherein said at least two webs are parallel.

38. The apparatus of claim 33, wherein said cathode is interposed between said one or more additional webs and said co-planar plurality of webs.

39. The apparatus of claim 1, wherein said deposition unit further comprises a sputtering chamber, said sputtering chamber including a target and means for sputtering said target to form a sputtered thin film on said continuous web substrates, said means for sputtering including means for forming a plasma between said target and said continuous web substrates.

40. The apparatus of claim 39, wherein said sputtered film is a back reflector layer.

41. The apparatus of claim 40, wherein said back reflector layer comprises ZnO, Al or Ag.

42. The apparatus of claim 39, wherein said sputtered film comprises a transparent conducting oxide.

43. The apparatus of claim 42, wherein said transparent conducting oxide comprises an element selected from the group consisting of Zn, In, Sn, and 0.

44. Apparatus for depositing a thin film layer on two co-planar pluralities of continuous web substrates comprising:
a pay-out unit, said pay-out unit providing a first co-planar plurality of continuous webs and a second co-planar plurality of continuous webs;
a deposition unit, said deposition unit receiving said first and second co-planar pluralities of continuous webs from said pay-out unit, said deposition unit including a deposition chamber, said deposition chamber including: a cathode; a first plasma region between said cathode and said first co-planar plurality of continuous webs; a second plasma region between said cathode and said second co-planar plurality of continuous webs; means for introducing electromagnetic energy into said first and second plasma regions; means for introducing process gases into said first and second plasma regions, said process gases including one or more deposition precursors, said one or more deposition precursors forming reactive species in said first and second plasma regions upon introduction of said electromagnetic energy, said reactive species forming a thin film layer on said first and second co-planar pluralities of continuous webs;
a take-up unit, said take-up unit receiving said first and second co-planar pluralities of continuous webs from said deposition unit.

45. The apparatus of claim 44, wherein said cathode is interposed between said first and second co-planar pluralities of continuous webs.

46. The apparatus of claim 44, wherein said first and second co-planar pluralities of continuous webs are parallel to said cathode.

47. The apparatus of claim 46, wherein said cathode is vertically oriented.

48. The apparatus of claim 47, wherein said first and second co-planar pluralities of continuous webs are transported horizontally.

49. An apparatus for depositing a thin film layer on a plurality of continuous web substrates comprising:
a pay-out unit, said pay-out unit providing a plurality of continuous web substrates;
a deposition unit, said deposition unit receiving said plurality of continuous webs from said pay-out unit, said deposition unit including a deposition chamber, said deposition chamber including: a cathode, said cathode not being interposed between any two of said plurality of continuous webs; a plasma region between said cathode and said plurality of continuous webs; means for introducing electromagnetic energy into said plasma region; means for introducing process gases into said plasma region, said process gases including one or more deposition precursors, said one or more deposition precursors forming reactive species in said plasma region upon introduction of said electromagnetic energy, said reactive species forming a thin film layer on said plurality of continuous webs;
a take-up unit, said take-up unit receiving said plurality of continuous webs from said deposition unit.

50. The apparatus of claim 49, wherein each of said plurality of continuous webs is transported in the same direction.

51. The apparatus of claim 49, wherein said plurality of webs is parallel to said cathode.

52. The apparatus of claim 49, wherein said cathode is vertically oriented.

53. A continuous web deposition apparatus including a continuous web and a continuous web supporter, said web supporter rotating in the direction of transport of said continuous web, said web supporter including a central notch having a lower support surface and an inside surface, said central notch aligned in said direction of transport, said central notch rotatably engaging said web, the edge of said web being inserted in said central notch.

54. The apparatus of claim 53, wherein a surface of said web is not in physical contact with said supporter.

55. The apparatus of claim 53, wherein said lower support surface is asymmetric with respect to the central cross-sectional plane of said supporter.

56. The apparatus of claim 55, wherein said lower support surface is angled.

57. The apparatus of claim 53, wherein said central notch is substantially V-shaped or substantially U-shaped.

58. The apparatus of claim 53, wherein said inside surface is not continuous.

59. The apparatus of claim 53, wherein said lower support surface is not continuous.

60. The apparatus of claim 53, further including flexible displacement means attached to said web supporter, said displacement means providing adjustment in the position of said web supporter in response to a disturbance in the motion of said web, said adjustment acting to counteract said motional disturbance thereby promoting more uniform transport of said web.

61. The apparatus of claim 53, wherein said apparatus includes a plurality of said web supporters.

62. The apparatus of claim 53, wherein said web is vertically oriented.

63. The apparatus of claim 53, wherein said web is transported horizontally.

64. The apparatus of claim 53, further including one or more additional continuous webs wherein each of said one or more additional webs is supported by one or more of said web supporters.

65. The apparatus of claim 53, wherein deposition is accomplished by plasma enhanced chemical vapor deposition.
